(19) United States
(12) Patent Application Publication
(10) Pub. No.: US 2015/0155401 A1
(43) Pub. Date: Jun. 4, 2015

(54) ELECTROCONDUCTIVE PASTE WITH ADHESION ENHANCER

(71) Applicant: Heraeus Precious Metals North America Conshohocken LLC, West Conshohocken, PA (US)

(72) Inventors: Eric Kurtz, Philadelphia, PA (US); Lindsey A. Karpowich, Philadelphia, PA (US); Weiming Zhang, Blue Bell, PA (US)

(21) Appl. No.: 14/406,764

(22) PCT Filed: Jun. 12, 2013
(86) PCT No.: PCT/US13/45312

§ 371 Date: Dec. 10, 2014

Related U.S. Application Data
(60) Provisional application No. 61/658,699, filed on Jun. 12, 2012.

(51) Int. Cl. H01L 31/0224; H01L 31/18; C09D 5/24

(52) U.S. Cl. CPC H01L 31/022425; C09D 5/24; H01L 31/18

(57) ABSTRACT

The present invention relates to an electroconductive paste useful in the manufacture of silicon solar cells and solar cell modules, especially for the backside of the silicon wafer. The electroconductive paste comprises metallic particles, glass frit, organic vehicle, and an adhesion enhancer. The adhesion enhancer comprises a metal or a metal oxide, or any other metal compound that will convert to metal or metal oxide at firing temperature. The adhesion enhancer comprises at least one metal selected from the group consisting of tellurium, tungsten, molybdenum, vanadium, nickel, antimony, magnesium, zirconium, silver, cobalt, cerium, and zinc, or oxides thereof. Preferably, the adhesion enhancer is tellurium or tellurium dioxide, and may be present in an amount of about 0.01-5 wt. % (based upon 100% total weight of the paste). The glass frits can be leaded or lead-free and may be present in an amount of about 1-10 wt. %. The metallic particles can be any of silver, aluminum, gold or nickel, or any alloys thereof, and can be present in an amount of about 40-75 wt. %. Another aspect of the present invention relates to a solar cell printed with an electroconductive paste composition on its backside, as well as an assembled solar cell module. Another aspect of the present invention relates to soldering pads formed by the present invention electroconductive paste composition on a silicon substrate, wherein the pull force required to remove the soldering pad from the silicon substrate is above 1 Newton. An additional aspect of the present invention relates to a method of producing a solar cell.

### RELATED APPLICATION

This application claims priority to U.S. Provisional Application Ser. No. 61/658,699, filed Jun. 12, 2012, the disclosure of which is incorporated herein by reference in its entirety.

### FIELD OF THE INVENTION

This invention relates to electroconductive paste compositions utilized in solar panel technology, especially for forming backside soldering pads. Specifically, in one aspect, the present invention is an electroconductive paste composition comprising conductive particles, glass frit, an organic vehicle and an adhesion enhancer comprising a metal or a metal oxide, or any other metal compound that will convert to metal or metal oxide at firing temperature. The adhesion enhancer comprises at least one element or oxide thereof selected from the group consisting of tellurium, tungsten, molybdenum, vanadium, nickel, antimony, magnesium, zirconium, silver, cobalt, cerium, and zinc. Preferably, the adhesion enhancer is tellurium or tellurium oxide. Further, another aspect of the present invention is a solar cell produced by applying an electroconductive paste to the backside of a silicon wafer to form soldering pads. Another aspect of the present invention is a solar panel comprising electrically interconnected solar cells. Lastly, another aspect of the present invention is a method of producing a solar cell.

### BACKGROUND OF THE INVENTION

Solar cells are devices that convert the energy of light into electricity using the photovoltaic effect. Solar power is an attractive green energy source because it is sustainable and produces only non-polluting by-products. Accordingly, a great deal of research is currently being devoted to developing solar cells with enhanced efficiency while continuously lowering material and manufacturing costs.

When light hits a solar cell, a fraction of the incident light is reflected by the surface and the remainder is transmitted into the solar cell. The photons of the transmitted light are absorbed by the solar cell, which is usually made of a semiconducting material such as silicon. The energy from the absorbed photons excites electrons of the semiconducting material from their atoms, generating electron-hole pairs. These electron-hole pairs are then separated by p-n junctions and collected by conductive electrodes applied on the solar cell surface.

The most common solar cells are those made of silicon. Specifically, a p-n junction is made from silicon by applying an n-type diffusion layer onto a p-type silicon substrate, coupled with two electrical contact layers or electrodes. In a p-type semiconductor, dopant atoms are added to the semiconductor in order to increase the number of free charge carriers (positive holes). Essentially, the doping material takes away weakly bound outer electrons from the semiconductor atoms. One example of a p-type semiconductor is silicon with a boron or aluminum dopant. Solar cells can also be made from n-type semiconductors. In an n-type semiconductor, the dopant atoms provide extra electrons to the host substrate, creating an excess of negative electron charge carriers. One example of an n-type semiconductor is silicon with a phosphorous dopant. In order to minimize reflection of the sunlight by the solar cell, an antireflective coating, such as silicon nitride, is applied to the n-type diffusion layer to increase the amount of light coupled into the solar cell.

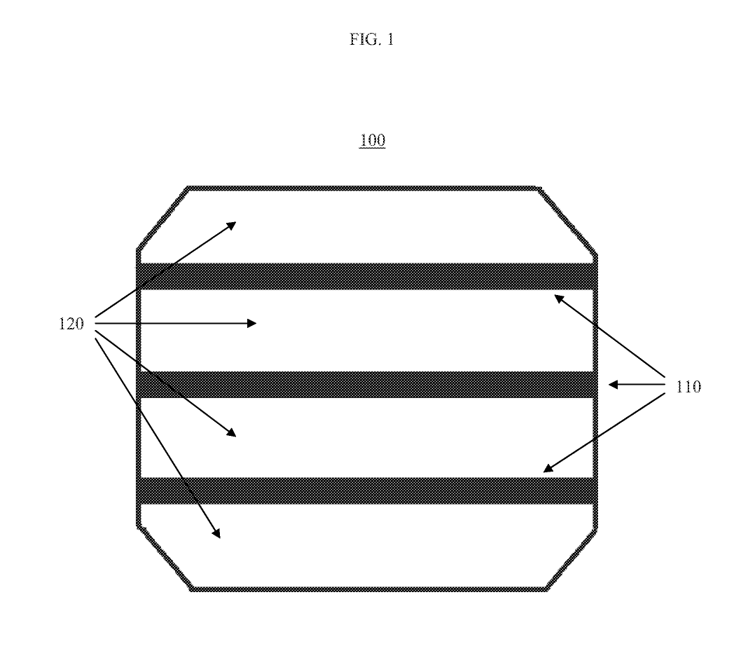

Solar cells typically have electroconductive pastes applied to both their front and back surfaces. The front side pastes result in the formation of electrodes that conduct the electricity generated from the exchange of electrons, as described above, while the backside pastes serve as solder joints for connecting solar cells in series via a solder coated conductive wire. To form a solar cell, a rear contact is first applied to the backside of the solar cell to form soldering pads, such as by screen printing a silver paste or silver/aluminum paste. Next, an aluminum backside paste is applied to the entire backside of the solar cell, slightly overlapping the soldering pads' edges, and the cell is then dried. FIG. 1 shows a silicon solar cell 100 having soldering pads 110 running across the length of the cell, with an aluminum backside 120 printed over the entire surface. Lastly, using a different type of electroconductive paste, a metal contact may be screen printed onto the front side antireflection layer to serve as a front electrode. This electrical contact layer on the face or front of the cell, where light enters, is typically present in a grid pattern made of finger lines and bus bars, rather than a complete layer, because the metal grid materials are typically not transparent to light. The silicon substrate, with the printed front side and backside paste, is then fired at a temperature of approximately 700-975° C. After firing, the front side paste etches through the antireflection layer, forms electrical contact between the metal grid and the semiconductor, and converts the metal pastes to metal electrodes. On the backside, the aluminum diffuses into the silicon substrate, acting as a dopant which creates a back surface field (BSF). This field helps to improve the efficiency of the solar cell.

The resulting metallic electrodes allow electricity to flow to and from solar cells connected in a solar panel. To assemble a panel, multiple solar cells are connected in series and/or in parallel and the ends of the electrodes of the first cell and the last cell are preferably connected to output wiring. The solar cells are typically encapsulated in a transparent thermal plastic resin, such as silicon rubber or ethylene vinyl acetate. A transparent sheet of glass is placed on the front surface of the encapsulating transparent thermal plastic resin. A back protecting material, for example, a sheet of polyethylene terephthalate coated with a film of polyvinyl fluoride having good mechanical properties and good weather resistance, is placed under the encapsulating thermal plastic resin. These layered materials may be heated in an appropriate vacuum furnace to remove air, and then integrated into one body by heating and pressing. Furthermore, since solar modules are typically left in the open air for a long time, it is desirable to cover the circumference of the solar cell with a frame material consisting of aluminum or the like.

A typical electroconductive paste for backside use contains metallic particles, glass frit, and an organic vehicle. These components must be carefully selected to take full advantage of the theoretical potential of the resulting solar cell. The soldering pads formed by the backside silver or silver/aluminum paste are particularly important, as soldering to an aluminum backside layer is practically impossible. The soldering pads may be formed as bars extending the length of the silicon substrate, or discrete segments arranged along the length of the silicone substrate. The soldering pads must adhere well to the silicon substrate, and must be able to withstand the mechanical manipulation of soldering a bonding wire, while having no detrimental effect on the efficiency of the solar cell.

A typical method used to test the adhesion of backside soldering pads is to apply a solder wire to the silver layer soldering pad and then measure the force required to peel off the soldering wire at a certain angle relative to the substrate, typically 180 degrees. Typically, a pull force of greater than 2 Newtons is the minimal requirement, with higher forces considered more desirable. Thus, compositions for backside pastes with improved adhesive strength are desired.

U.S. Patent Application Publication No. 2011/0308595 A1 discloses a thick-film paste for printing on the front-side of a solar cell device having one or more insulating layers. The thick-film paste comprises an electrically conductive metal and lead-tellurium-oxide dispersed in an organic medium. The lead-tellurium-oxide is present in an amount of 0.5 to 15 wt. % of solids of the paste and the molar ratio of lead to tellurium is between 5/95 and 95/5. The lead-tellurium-oxide (Pb—Te—O) is prepared by mixing TeO₂ and lead oxide powders, heating the powder mixture in air or an oxygen-containing atmosphere to form a melt, quenching the melt, grinding and ball-milling the quenched material, and screening the milled material to provide a powder with the desired particle size.

U.S. Pat. No. 5,066,621 discloses a sealing glass composition comprising, in wt. %, 13-50% lead oxide, 20-50% vanadium oxide, 2-40% tellurium oxide, up to 40% selenium oxide, up to 10% phosphorous oxide, up to 5% niobium oxide, up to 20% bismuth oxide, up to 5% copper oxide and up to 10% boron oxide. It also discloses an electrically conductive formulation comprising, in wt. %, 50-77% silver, 8-34% of a sealing glass composition as described previously, 0.2-1.5% resin and thixotrope, and 10-20% organic solvent. The disclosed sealing glass composition is used to bond semiconductor chips, i.e., “dies,” to ceramic substrates, in the field of semiconductor chip packaging.

U.S. Patent Application Publication No. 2011/0192457 discloses an electroconductive paste composition used to form surface electrodes on silicon solar cells. The paste contains an electroconductive particle, an organic binder, a solvent, a glass frit, and an organic compound including alkaline earth metal, a metal with a low melting point or a compound affiliated with a metal with a low melting point. The electroconductive paste composition of the '457 publication is for the forming of front (light receiving) surface electrodes of a silicon wafer.

U.S. Pat. Nos. 7,736,546 and 7,935,279 disclose lead-free glass frits with no intentionally added lead which comprise TeO₂ and one or more of Bi₂O₃, SiO₂ and combinations thereof. The patents also disclose conductive inks comprising the glass frits and articles having such conductive inks applied. The electroconductive paste compositions of the '546 and '279 patents are also for the forming of front (light receiving) surface electrodes of a silicon wafer.

European Patent No. EP 1 713 095 A2 discloses a conductive silver paste for use in front side metallization of a solar cell device, which comprises 70-85 wt. % silver powder, less than 6 wt. % manganese-containing additive, less than 4 wt. % glass frits having a softening point in the range of 300-600° C., all dispersed in about 5-30 wt. % organic medium.

### SUMMARY OF THE INVENTION

An object of the present invention is to develop a backside paste for use in forming soldering pads on a solar cell which has improved adhesive strength.

The present invention provides an electroconductive paste composition for use in forming backside soldering pads on a solar cell comprising metallic particles, glass frits, organic vehicle, and an adhesion enhancer comprising a metal or a metal oxide, or any other metal compound that will convert to metal or metal oxide at firing temperature, wherein the adhesion enhancer comprises at least one metal selected from the group consisting of tellurium, tungsten, molybdenum, vanadium, nickel, antimony, magnesium, zirconium, silver, cobalt, cerium, and zinc, or oxides thereof.

According to one aspect of the invention, the adhesion enhancer is at least one metal selected from the group consisting of tellurium, tungsten, molybdenum, nickel, and zinc, and preferably tellurium.

According to another aspect of the invention, the adhesion enhancer is at least one metal oxide selected from the group consisting of tellurium dioxide, nickel oxide, magnesium oxide, zirconium dioxide, tungsten oxide, silver oxide, cobalt oxide and cerium oxide, and preferably tellurium dioxide.

According to a further aspect of the invention, the adhesion enhancer is about 0.01-5 wt. % of the electroconductive paste composition. The adhesion enhancer may also be about 0.05-2.5 wt. % of the electroconductive paste composition, preferably about 0.05-1 wt. %.

According to an additional aspect of the invention, the adhesion enhancer is dispersed within the glass frits.

According to a further aspect of the invention, the adhesion enhancer is dispersed within the paste composition independent from the glass frits.

According to another aspect of the invention, the metallic particles are about 30-75 wt. % of the electroconductive paste composition. In one embodiment of the invention, the metallic particles are no more than 60 wt. % of the electroconductive paste composition (e.g., about 30-60 wt. %). In another embodiment of the invention, the metallic particles are no more than 50 wt. % of the electroconductive paste composition (e.g., about 30-50 wt. %).

According to an additional aspect of the invention, the metallic particles are at least one of silver, aluminum, gold and nickel, or any alloys thereof, and preferably are silver.

According to a further aspect of the invention, the glass frits are about 1-10 wt. % of the electroconductive paste composition. In one embodiment of the invention, the glass frits comprise lead oxide. In another embodiment of the invention, the glass frits comprise no intentionally added lead. In a further embodiment of the invention, the glass frits comprise bismuth oxide and no intentionally added lead. In an additional embodiment of the invention, the glass frits comprise at least one of Bi—B—Li-oxide, Bi—Zn—B-oxide, Bi—Si—Zn—B-oxide or Bi—Si-oxide.

According to another aspect of the invention, the organic vehicle is about 20-60 wt. % of the electroconductive paste composition, preferably about 30-50 wt. %, more preferably about 45 wt. %. In one embodiment of the invention, the organic vehicle comprises a binder, a surfactant, an organic solvent and a thixatropic agent. In another embodiment of the invention, the binder is at least one of ethylcellulose or phenolic resin, acrylic, polyvinyl butyral or polyester resin, polycarbonate, polyethylene or polyurethane resins, or rosin derivatives. In a further embodiment of the invention, the surfactant is at least one of polyethylene oxide, polyethylene glycol, benzotriazole, poly(ethyleneglycol)acetic acid, lauric acid, oleic acid, capric acid, myristic acid, linolic acid, stearic acid, palmitic acid, stearate salts, palmitate salts, and mixtures thereof. In an additional embodiment of the invention, the organic solvent is at least one of carbitol, terpineol, hexyl carbitol, texanol, butyl carbitol, butyl carbitol acetate, dimethyladipate or glycol ether.

The present invention also provides a solar cell comprising a silicon wafer having a front side and a backside, and a soldering pad formed on the silicon wafer produced from any electroconductive paste as previously described.

According to one aspect of the invention, the soldering pad is formed on the backside of the solar cell.

In one embodiment of the invention, the soldering pad may be removed from the silicon wafer with a pull force equal to or greater than 1-Newtons. In another embodiment of the invention, the soldering pad may be removed from the silicon wafer with a pull force equal to or greater than 2-Newtons. In an additional embodiment of the invention, the soldering pad may be removed from the silicon wafer with a pull force equal to or greater than 3-Newtons. In a further embodiment of the invention, the soldering pad may be removed from the silicon wafer with a pull force equal to or greater than 5-Newtons. In yet another embodiment, the pull force required to remove the soldering pad from the silicon wafer is at least 1 Newton, 2 Newtons, 3 Newtons, 4 Newtons, or 5 Newtons.

According to another aspect of the invention, the soldering pad is formed from an electroconductive paste comprising about 30-75 wt. % of metallic particles. According to a further aspect of the invention, the soldering pad is formed from an electroconductive paste comprising no more than 60 wt. % of metallic particles (e.g., about 30-60 wt. %). According to an additional aspect of the invention, the soldering pad is formed from an electroconductive paste comprising no more than 50 wt. % of metallic particles (e.g., about 30-50 wt. %).

According to a further aspect of the invention, an electrode is formed on the front side of the silicon wafer.

According to an additional aspect of the invention, the front side of the silicon wafer comprises an anti-reflective layer.

The present invention further provides a solar cell module comprising electrically interconnected solar cells as previously described.

The present invention also provides a method of producing of a solar cell, comprising the steps of providing a silicon wafer having a front side and a backside, applying any electroconductive paste composition as previously described onto the backside of the silicon wafer, and firing the silicon wafer according to an appropriate profile.

According to one aspect of the invention, the silicon wafer has an antireflective coating on the front side.

According to another aspect of the invention, the method further comprises the step of applying an aluminum-comprising paste to the backside of the silicon wafer overlapping the edges of the electroconductive paste composition as previously described.

According to a further aspect of the invention, the method further comprises the step of applying a silver-comprising paste to the front side of the silicon wafer.

According to an additional aspect of the invention, the step of applying the aluminum-comprising paste is by screen printing.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawing, FIG. 1, which is an exemplary view of the backside of a silicon solar cell having printed silver soldering pads running across the length of the cell.

### DETAILED DESCRIPTION

The present invention relates to an electroconductive paste composition useful for application to the backside of a solar cell. The electroconductive paste composition preferably comprises metallic particles, glass frit, an adhesion enhancer, and an organic vehicle. While not limited to such an application, such pastes may be used to form an electrical contact layer or electrode in a solar cell, as well to form soldering pads used to interconnect solar cells in a module. Specifically, the pastes may be applied to the front side of a solar cell or to the backside of a solar cell.

FIG. 1 illustrates exemplary soldering pads 110 deposited on the backside of a silicon solar cell 100. In this particular example, screen printed silver soldering pads run across the length of the cell. In other configurations, the soldering pads may be of discrete segments. The soldering pads can be of any shape and size such as those known in the art. A second backside paste, e.g., paste comprising aluminum, were also printed on the backside of the silicon wafer contacting the soldering pads, forming backside electrodes 120 of the solar cell when fired.

One aspect of the present invention relates to the composition of an electroconductive paste used to form backside soldering pads. A desired backside paste is one which has high adhesive strength to allow for optimal solar cell mechanical reliability, while also optimizing the solar cell's electrical performance. The electroconductive paste composition according to the present invention is comprised of metallic particles, glass frit, organic vehicle, and an adhesion enhancer, whereby the presence of the metal adhesion enhancer or metal oxide adhesion enhancer improves the paste's adhesive strength. The adhesion enhancer comprises at least one metal, or oxide thereof, selected from the group consisting of tellurium, tungsten, molybdenum, vanadium, antimony, magnesium, zirconium, silver, cobalt, cerium and zinc. Preferably, the adhesion enhancer is tellurium or tellurium dioxide. The adhesion enhancer can be dispersed within the glass frit, or within the paste composition independent from the glass frit.

One method used to measure the adhesive strength, also known as the pull force, of a backside paste is to apply a solder wire to the electroconductive paste layer (soldering pad) which has been printed on the backside of a silicon solar cell. A standard soldering wire is applied to the soldering pad either by an automated machine or manually with a hand held solder gun. In the present invention, a 2.0×0.20 mm copper ribbon with approximately 20 μm 62/36/2 solder coating was used, although other methods common in the industry and known in the art may be used. With the copper wire soldered to the length of the soldering pad, a tailing end of the ribbon is peeled back at approximately 180° and pulled at a constant speed, while a force gauge records the pull force data at some set sampling rate.

When evaluating exemplary pastes, this solder and pull process is typically completed four times on four separate backside soldering pads to minimize variation in the data that normally results from the soldering process. One individual measurement from one experiment is not highly reliable, as discrete variations in the soldering process can affect the results. Therefore, an overall average from four pulls is obtained and the averaged pull forces are compared between pastes. Typically, a minimum of 1 Newton pull force is desirable. The acceptable industry standard for adhesive strength is typically above 2 Newtons. Stronger adhesion with a pull force of at least 3 Newtons, or in some instances, greater than 5 Newtons may also be desirable.

The adhesive properties of an electroconductive backside paste are affected by the paste's composition. The present invention provides an electroconductive paste composition for use in forming backside soldering pads on a solar cell comprising metallic particles, glass frits, organic vehicle, and an adhesion enhancer comprising a metal or a metal oxide, or any other metal compound that will convert to metal or metal oxide at firing temperature, wherein the adhesion enhancer comprises at least one metal selected from the group consisting of tellurium, tungsten, molybdenum, vanadium, nickel, antimony, magnesium, zirconium, silver, cobalt, cerium, and zinc, or oxides thereof.

One embodiment of the present invention is an electroconductive paste comprising about 30-75 wt. % conductive particles, about 1-10 wt. % glass frit, about 20-60 wt. % organic vehicle, and about 0.01-5 wt. % of at least one of the following metals as an adhesion enhancer: tungsten (W), molybdenum (Mo), nickel (Ni), zinc (Zn), and tellurium (Te), based upon 100% total weight of the paste. Preferably, the metal is tellurium. In another preferred embodiment, the paste comprises approximately 0.01-2.5 wt. % tellurium metal, and more preferably about 0.01-1 wt. %.

Another embodiment of the present invention is an electroconductive paste comprising about 30-75 wt. % conductive particles, about 1-10 wt. % glass frit, about 20-60 wt. % organic vehicle and about 0.01-5 wt. % of at least one of the following metal oxides as an adhesion enhancer: tellurium dioxide (TeO₂), nickel oxide (NiO), magnesium oxide (MgO), zirconium dioxide (ZrO₂), tungsten oxide (WO₃), silver oxide (AgO), cobalt oxide (CoO) and cerium oxide (CeO₂), based upon 100% total weight of the paste. In a preferred embodiment, the metal oxide is tellurium dioxide. Preferably, the paste comprises approximately 0.01-2.5 wt. % tellurium dioxide, and more preferably about 0.01-1 wt. %. In yet another preferred embodiment, the average particle size of the tellurium dioxide is less than 1 μm, preferably less than 0.6 μm. As a general observation, without limiting the scope of the present invention, smaller tellurium dioxide particle size aids the distribution within the paste composition and provides better adhesive and electrical properties.

According to yet another embodiment, the adhesion enhancer is at least one of the following metals: tungsten, molybdenum, vanadium, antimony, magnesium, zirconium, silver, cobalt, and cerium or oxides thereof.

### Conductive Metal Particles

Conductive metallic particles known in the art suitable for uses as solar cell surface electrodes that are also easy to solder, and mixtures or alloys thereof, can be used with the present invention. In one embodiment, the conductive particles are at least one of silver, aluminum, gold and nickel, or any alloys thereof. The conductive particles are typically about 30-75 wt. %, or about 35-70 wt. %, of the paste composition. In another embodiment, the conductive particles are less than about 60 wt. % of the paste (e.g., about 30-60 wt. %). In another embodiment, the conductive particles are less than 50 wt. % of the paste (e.g., about 30-50 wt. %). Lower conductive particle content typically also lowers the cost of the paste composition. In a preferred embodiment, the conductive particles are silver. In another embodiment, the conductive particles are a mixture of silver and aluminum.

The conductive particles may be present as elemental metal, one or more metal derivatives, or a mixture thereof. Suitable silver derivatives include, for example, silver alloys and/or silver salts, such as silver halides (e.g., silver chloride), silver nitrate, silver acetate, silver trifluoroacetate, silver orthophosphate, and combinations thereof.

The conductive particles can exhibit a variety of shapes, surfaces, sizes, surface area to volume ratios, oxygen content and oxide layers. A large number of shapes are known in the art. Some examples are spherical, angular, elongated (rod or needle like) and flat (sheet like). Conductive metallic particles may also be present as a combination of particles of different shapes. Metallic particles with a shape, or combination of shapes, which favors adhesion are preferred according to the invention. One way to characterize such shapes without considering the surface nature of the particles is through the following parameters: length, width and thickness. In the context of the invention, the length of a particle is given by the length of the longest spatial displacement vector, both endpoints of which are contained within the particle. The width of a particle is given by the length of the longest spatial displacement vector perpendicular to the length vector defined above both endpoints of which are contained within the particle. The thickness of a particle is given by the length of the longest spatial displacement vector perpendicular to both the length vector and the width vector, both defined above, both endpoints of which are contained within the particle.

In one embodiment according to the invention, metallic particles with shapes as uniform as possible are preferred (i.e. shapes in which the ratios relating the length, the width and the thickness are as close as possible to 1, preferably all ratios lying in a range from about 0.7 to about 1.5, more preferably in a range from about 0.8 to about 1.3 and most preferably in a range from about 0.9 to about 1.2). Examples of preferred shapes for the metallic particles in this embodiment are spheres and cubes, or combinations thereof, or combinations of one or more thereof with other shapes. In another embodiment according to the invention, metallic particles are preferred which have a shape of low uniformity, preferably with at least one of the ratios relating the dimensions of length, width and thickness being above about 1.5, more preferably above about 3 and most preferably above about 5. Preferred shapes according to this embodiment are flake shaped, rod or needle shaped, or a combination of flake shaped, rod or needle shaped with other shapes.

Another way to characterize the shape and surface of a metallic particle is by its surface area to volume ratio. The lowest value for the surface area to volume ratio of a particle is embodied by a sphere with a smooth surface. The less uniform and uneven a shape is, the higher its surface area to volume ratio will be. In one embodiment according to the invention, metallic particles with a high surface area to volume ratio are used, preferably in a range from about 1.0×10⁷ to about 1.0×10⁹ m⁻¹, more preferably in a range from about 5.0×10⁷ to about 5.0×10⁸ m⁻¹ and most preferably in a range from about 1.0×10⁸ to about 5.0×10⁸ m⁻¹. In another embodiment according to the invention, metallic particles with a low surface area to volume ratio are used, preferably in a range from about 6×10⁵ to about 8.0×10⁶ m⁻¹, more preferably in a range from about 1.0×10⁶ to about 6.0×10⁶ m⁻¹ and most preferably in a range from about 2.0×10⁶ to about 4.0×10⁶ m⁻¹.

The particle diameter d₅₀ and the associated values, d₁₀ and d₉₀, are characteristics of particles well known to the person skilled in the art. It is preferred according to the invention that the median particle diameter d₅₀ of the metallic particles lie in a range from about 2 to about 4 μm, more preferably in a range from about 2.5 to about 3.5 m and most preferably in a range from about 2.8 to about 3.2 μm. The determination of the particle diameter d₅₀ is well known to a person skilled in the art.

In one embodiment of the invention, the metallic particles have a d₁₀ greater than about 1.5 μm, preferably greater than about 1.7 μm, more preferably greater than about 1.9 μm. The value of d₁₀ should not exceed the value of d₅₀.

In one embodiment of the invention, the metallic particles have a d₉₀ less than about 6 μm, preferably less than about 5 μm, more preferably less than about 4.5 μm. The value of d₉₀ should not be less than the value of d₅₀.

The metallic particles may be present with a surface coating. Any such coating known in the art, and which is considered to be suitable in the context of the invention, may be employed on the metallic particles. Preferred coatings according to the invention are those coatings which promote adhesion characteristics of the electroconductive paste. If such a coating is present, it is preferred according to the invention for that coating to correspond to no more than about 10 wt. %, preferably no more than about 8 wt. %, most preferably no more than about 5 wt. %, in each case based on the total weight of the metallic particles.

### Glass Frit

In another preferred embodiment, the glass frit may be about 1-10 wt. % of the paste composition. Glass frits known in art suitable for backside pastes can be used with the present invention. Preferred glass frits are powders of amorphous or partially crystalline solids which exhibit a glass transition. The glass transition temperature T_{g} is the temperature at which an amorphous substance transforms from a rigid solid to a partially mobile undercooled melt upon heating. Methods for the determination of the glass transition temperature are well known to the person skilled in the art. Preferably, the glass transition temperature is below the desired firing temperature of the electroconductive paste. According to the invention, preferred glass frits have a glass transition temperature in a range from about 250° C. to about 700° C., preferably in a range from about 300° C. to about 600° C. and most preferably in a range from about 350° C. to about 500° C.

In the context of the invention, the glass frit present in the electroconductive paste preferably comprises elements, oxides, and/or compounds which generate oxides upon heating, other compounds, or mixtures thereof. The glass frit may comprise lead, or can be substantially lead-free. The lead-based glass frit comprises lead oxide or other lead-based compounds including, but not limited to, salts of lead halides, lead chalcogenides, lead carbonate, lead sulfate, lead phosphate, lead nitrate and organometallic lead compounds or compounds that can form lead oxides or salts during thermal decomposition. The glass frit may include other oxides or compounds known in the art. For example, silicon, boron, aluminum, bismuth, lithium, sodium, magnesium, zinc, titanium, or zirconium oxides or compounds may be used. Other glass matrix formers or glass modifiers, such as germanium oxide, vanadium oxide, tungsten oxide, molybdenum oxides, niobium oxides, tin oxides, indium oxides, other alkaline and alkaline earth metal (such as K, Rb, Cs and Be, Ca, Sr, Ba) compounds, rare earth oxides (such as La₂O₃, cerium oxides), phosphorus oxides or metal phosphates, transition metal oxides (such as copper oxides and chromium oxides), or metal halides (such as lead fluorides and zinc fluorides) may also be part of the glass composition. In one embodiment of the present invention, lead free glass frits may comprise bismuth and other oxides, for example, without limiting the scope of the invention, bismuth-boron-lithium-oxide, bismuth-silicon-oxide, bismuth-silicon-zinc-boron-oxide or a bismuth-zinc-boron-oxide.

It is well known to the person skilled in the art that glass frit particles can exhibit a variety of shapes, surface natures, sizes, surface area to volume ratios and coating layers. A large number of shapes of glass frit particles are known in the art. Some examples are spherical, angular, elongated (rod or needle like) and flat (sheet like). Glass frit particles may also be present as a combination of particles of different shapes. Glass frit particles with a shape, or combination of shapes, which favours advantageous sintering, adhesion, electrical contact and electrical conductivity of the produced electrode are preferred according to the invention.

A way to characterise the shape and surface of a particle is by its surface area to volume ratio. The less uniform and uneven a shape is, the higher its surface area to volume ratio will be. In one embodiment according to the invention, glass frit particles with a high surface area to volume ratio are preferred, preferably in a range from about 1.0×10⁷ to about 1.0×10⁹ m⁻¹, more preferably in a range from about 5.0×10⁷ to about 5.0×10⁸ m⁻¹ and most preferably in a range from about 1.0×10⁸ to about 5.0×10 m⁻¹. In another embodiment according to the invention, glass frit particles with a low surface area to volume ratio are preferred, preferably in a range from about 6×10⁵ to about 8.0×10⁶ m⁻¹, more preferably in a range from about 1.0×10⁶ to about 6.0×10⁶ m⁻¹ and most preferably in a range from about 2.0×10⁶ to about 4.0×10⁶ m.

The average particles diameter d₅₀, and the associated parameters d₁₀ and d₉₀ are characteristics of particles well known to the person skilled in the art. It is preferred according to the invention that the median particle diameter d₅₀ of the glass frit is less than 1 μm, preferably less than 0.6 μm. As a general observation, without limiting the scope of the present invention, smaller glass particle size aids the distribution within the paste composition and provides better adhesive and electrical properties. The determination of the particles diameter d₅₀ is well known to the person skilled in the art.

The glass frit particles may be present with a surface coating. Any such coating known in the art and which is considered to be suitable in the context of the invention can be employed on the glass frit particles. Preferred coatings according to the invention are those coatings which promote improved adhesion of the electroconductive paste. If such a coating is present, it is preferred according to the invention for that coating to correspond to no more than about 10 wt. %, preferably no more than about 8 wt. %, most preferably no more than about 5 wt. %, in each case based on the total weight of the glass frit particles.

### Organic Vehicle

Preferred organic vehicles in the context of the invention are solutions, emulsions or dispersions based on one or more solvents, preferably an organic solvent, which ensure that the constituents of the electroconductive paste are present in a dissolved, emulsified or dispersed form. Preferred organic vehicles are those which provide optimal stability of constituents within the electroconductive paste and endow the electroconductive paste with a certain viscosity to optimize printability.

The organic vehicle may be about 20-60 wt. % of the paste composition, preferably about 30-50 wt. %, and even more preferably about 45 wt. %. The organic vehicle typically comprises a binder, a surfactant, an organic solvent and a thixatropic agent.

Preferred binders in the context of the invention are those which contribute to the formation of an electroconductive paste with favorable stability, printability and viscosity. Binders are well known in the art. All binders which are known in the art and which are considered to be suitable in the context of this invention can be employed as the binder in the organic vehicle. Preferred binders according to the invention (which often fall within the category termed “resins”) are polymeric binders, monomeric binders, and binders which are a combination of polymers and monomers. Polymeric binders can also be copolymers wherein at least two different monomeric units are contained in a single molecule. According to one embodiment, the binder may be selected from a group consisting of ethylcellulose or phenolic resin, acrylic, polyvinyl butyral or polyester resin, polycarbonate, polyethylene or polyurethane resins, rosin derivatives, or any other binder known in the art, or any combination of any of the foregoing.

Preferred surfactants in the context of the invention are those which contribute to the formation of an electroconductive paste with favorable stability, printability, and viscosity. Surfactants are well known to the person skilled in the art. All surfactants which are known in the art and which are considered to be suitable in the context of this invention can be employed as the surfactant in the organic vehicle. Preferred surfactants in the context of the invention are those based on linear chains, branched chains, aromatic chains, fluorinated chains, siloxane chains, polyether chains and combinations thereof. Preferred surfactants are single chained double chained or poly chained. Preferred surfactants according to the invention have non-ionic, anionic, cationic, or zwitterionic heads. Preferred surfactants are polymeric and monomeric or a mixture thereof. According to one embodiment, the surfactant is selected from a group consisting of polyethylene oxide, polyethylene glycol, benzotriazole, poly(ethyleneglycol)acetic acid, lauric acid, oleic acid, capric acid, myristic acid, linolic acid, stearic acid, palmitic acid, stearate salts, palmitate salts, and mixtures thereof, or any other surfactants known in the art.

Preferred solvents according to the invention are constituents of the electroconductive paste which are removed from the paste to a significant extent during firing, preferably those which are present after firing with an absolute weight reduced by at least about 80% compared to before firing, preferably reduced by at least about 95% compared to before firing. Preferred solvents according to the invention are those which allow an electroconductive paste to be formed which has favourable viscosity, printability and stability. Solvents are well known in the art. All solvents which are known in the art and which are considered to be suitable in the context of this invention can be employed as the solvent in the organic vehicle. According to one embodiment, the organic solvent is selected from a group consisting of carbitol, terpineol, hexyl carbitol, texanol, butyl carbitol, butyl carbitol acetate, dimethyladipate or glycol ether, or any other solvent known in the art, or any combination of the foregoing.

The paste composition may further include one or more inorganic additives. The inorganic additive is about 0-2 wt. % of the paste composition and can be a wide variety of inorganic compounds known to one skilled in the art. The additive may include metals, metal oxides, salts, or any compounds that can generate metal oxides during firing, and any mixtures thereof. Preferred additives in the organic vehicle are those additives which are distinct from the aforementioned vehicle components and which contribute to favorable properties of the electroconductive paste. Additives known in the art and which are considered to be suitable in the context of the invention can be employed as an additive in the organic vehicle. Preferred additives according to the invention are thixotropic agents, viscosity regulators, stabilising agents, inorganic additives, thickeners, emulsifiers, dispersants or pH regulators. Preferred thixotropic agents in this context are carboxylic acid derivatives, preferably fatty acid derivatives or combinations thereof. Preferred fatty acid derivatives are C₉H₁₉COOH (capric acid), C₁H₂₃COOH (Lauric acid), C₁₃H₂₇COOH (myristic acid) C₁₅H₃₁COOH (palmitic acid), C₁₇H₃₅COOH (stearic acid) C₁₈H₃₄O₂ (oleic acid), C₁₈H₃₂O₂ (linoleic acid) or combinations thereof. A preferred combination comprising fatty acids in this context is castor oil.

### Forming the Electroconductive Paste

The electroconductive paste composition may be prepared by any method for preparing a paste composition known in the art. As an example, without limitation, the paste components may be mixed, such as with a mixer, then passed through a three roll mill, for example, to make a dispersed uniform paste.

### Silicon Solar Cells

The building block of a solar cell is a silicon wafer. Preferred wafers according to the invention have regions, among other regions of the solar cell, capable of absorbing light with high efficiency to yield electron-hole pairs and separating holes and electrons across a boundary with high efficiency, preferably across a p-n junction boundary. Preferred wafers according to the invention are those comprising a single body made up of a front doped layer and a back doped layer, as discussed more fully herein.

It is preferred for that wafer to consist of appropriately doped tetravalent elements, binary compounds, tertiary compounds or alloys. Preferred tetravalent elements in this context are Si, Ge or Sn, preferably Si. Preferred binary compounds are combinations of two or more tetravalent elements, binary compounds of a group III element with a group V element, binary compounds of a group II element with a group VI element or binary compounds of a group IV element with a group VI element. Preferred combinations of tetravalent elements are combinations of two or more elements selected from Si, Ge, Sn or C, preferably SiC. The preferred binary compounds of a group III element with a group V element is GaAs. It is most preferred according to the invention for the wafer to be based on Si. Si, as the most preferred material for the wafer, is referred to explicitly throughout the rest of this application. Sections of the following text in which Si is explicitly mentioned also apply for the other wafer compositions described above.

Where the front doped layer and back doped layer of the wafer meet is the p-n junction boundary. In an n-type solar cell, the back doped layer is doped with electron donating n-type dopant and the front doped layer is doped with electron accepting or hole donating p-type dopant. In a p-type solar cell, the back doped layer is doped with p-type dopant and the front doped layer is doped with n-type dopant. It is preferred according to the invention to prepare a wafer with a p-n junction boundary by first providing a doped Si substrate and then applying a doped layer of the opposite type to one face of that substrate.

Doped Si substrates are well known to the person skilled in the art. The doped Si substrate can be prepared in any way known to the person skilled in the art and which he considers to be suitable in the context of the invention. Preferred sources of Si substrates according to the invention are mono-crystalline Si, multi-crystalline Si, amorphous Si and upgraded metallurgical Si, mono-crystalline Si or multi-crystalline Si being most preferred.

Doping to form the doped Si substrate can be carried out simultaneously by adding dopant during the preparation of the Si substrate or can be carried out in a subsequent step. Doping subsequent to the preparation of the Si substrate can be carried out for example by gas diffusion epitaxy. Doped Si substrates are also readily commercially available. According to the invention it is one option for the initial doping of the Si substrate to be carried out simultaneously to its formation by adding dopant to the Si mix. According to the invention it is one option for the application of the front doped layer and the highly doped back layer, if present, to be carried out by gas-phase epitaxy. This gas phase epitaxy is preferably carried out at a temperature in a range from about 500° C. to about 900° C., more preferably in a range from about 600° C. to about 800° C. and most preferably in a range from about 650° C. to about 750° C. at a pressure in a range from about 2 kPa to about 100 kPa, preferably in a range from about 10 to about 80 kPa, most preferably in a range from about 30 to about 70 kPa.

It is known to the person skilled in the art that Si substrates can exhibit a number of shapes, surface textures and sizes. The shape can be one of a number of different shapes including cuboid, disc, wafer and irregular polyhedron amongst others. The preferred shape according to the invention is wafer shaped where that wafer is a cuboid with two dimensions which are similar, preferably equal and a third dimension which is significantly less than the other two dimensions. Significantly less in this context is preferably at least a factor of about 100 smaller.

A variety of surface types are known to the person skilled in the art. According to the invention Si substrates with rough surfaces are preferred. One way to assess the roughness of the substrate is to evaluate the surface roughness parameter for a sub-surface of the substrate which is small in comparison to the total surface area of the substrate, preferably less than about one hundredth of the total surface area, and which is essentially planar. The value of the surface roughness parameter is given by the ratio of the area of the subsurface to the area of a theoretical surface formed by projecting that subsurface onto the flat plane best fitted to the subsurface by minimising mean square displacement. A higher value of the surface roughness parameter indicates a rougher, more irregular surface and a lower value of the surface roughness parameter indicates a smoother, more even surface. According to the invention, the surface roughness of the Si substrate is preferably modified so as to produce an optimum balance between a number of factors including but not limited to light absorption and adhesion of fingers to the surface.

The two larger dimensions of the Si substrate can be varied to suit the application required of the resultant solar cell. It is preferred according to the invention for the thickness of the Si wafer to lie below about 0.5 mm more preferably below about 0.3 mm and most preferably below about 0.2 mm. Some wafers have a minimum size of 0.01 mm or more.

It is preferred according to the invention for the front doped layer to be thin in comparison to the back doped layer. It is preferred according to the invention for the front doped layer to have a thickness lying in a range from about 0.1 to about 10 μm, preferably in a range from about 0.1 to about 5 μm and most preferably in a range from about 0.1 to about 2 μm.

A highly doped layer can be applied to the back face of the Si substrate between the back doped layer and any further layers. Such a highly doped layer is of the same doping type as the back doped layer and such a layer is commonly denoted with a +(n⁺-type layers are applied to n-type back doped layers and p⁺-type layers are applied to p-type back doped layers). This highly doped back layer serves to assist metallisation and improve electroconductive properties at the substrate/electrode interface area. It is preferred according to the invention for the highly doped back layer, if present, to have a thickness in a range from about 1 to about 100 μm, preferably in a range from about 1 to about 50 m and most preferably in a range from about 1 to about 15 μm.

### Dopants

Preferred dopants are those which, when added to the Si wafer, form a p-n junction boundary by introducing electrons or holes into the band structure. It is preferred according to the invention that the identity and concentration of these dopants is specifically selected so as to tune the band structure profile of the p-n junction and set the light absorption and conductivity profiles as required. Preferred p-type dopants according to the invention are those which add holes to the Si wafer band structure. They are well known to the person skilled in the art. All dopants known to the person skilled in the art and which he considers to be suitable in the context of the invention can be employed as p-type dopant. Preferred p-type dopants according to the invention are trivalent elements, particularly those of group 13 of the periodic table. Preferred group 13 elements of the periodic table in this context include but are not limited to B, Al, Ga, In, Tl or a combination of at least two thereof, wherein B is particularly preferred.

Preferred n-type dopants according to the invention are those which add electrons to the Si wafer band structure. They are well known to the person skilled in the art. All dopants known to the person skilled in the art and which he considers to be suitable in the context of the invention can be employed as n-type dopant. Preferred n-type dopants according to the invention are elements of group 15 of the periodic table. Preferred group 15 elements of the periodic table in this context include N, P, As, Sb, Bi or a combination of at least two thereof, wherein P is particularly preferred.

As described above, the various doping levels of the p-n junction can be varied so as to tune the desired properties of the resulting solar cell.

### Solar Cells

A contribution to achieving at one of the aforementioned objects is made by a process for producing a solar cell at least comprising the following as process steps:
i) provision of a solar cell precursor as described above (i.e., silicon wafer), in particular combining any of the above described embodiments; and
ii) firing of the solar cell precursor to obtain a solar cell.

### Printing

It is preferred according to the invention that the front and back electrodes are applied by applying an electroconductive paste and then firing said electroconductive paste to obtain a sintered body. The electroconductive paste can be applied in any manner known to the person skilled in that art and which he considers suitable in the context of the invention including, but not limited to, impregnation, dipping, pouring, dripping on, injection, spraying, knife coating, curtain coating, brushing or printing or a combination of at least two thereof, wherein preferred printing techniques are ink-jet printing, screen printing, tampon printing, offset printing, relief printing or stencil printing or a combination of at least two thereof. It is preferred according to the invention that the electroconductive paste is applied by printing, preferably by screen printing. It is preferred according to the invention that the screens have parameters of 250 to 325 mesh, 5 to 15 um emulsion thickness, and 20 to 40 um wire diameter, most preferably 280 mesh, 5 um emulsion thickness, and 35 um wire diameter.

### Firing

Firing is necessary to sinter the printed soldering pads so as to form solid conductive bodies. Firing is well known to the person skilled in the art and can be effected in any manner known to him and which he considers suitable in the context of the invention. It is preferred in the context of the invention that firing be carried out above the glass transition temperature of the glass frit.

According to the invention the preferred peak firing temperature is about 700-975° C., measured via a data logger with a connected thermocouple attached to a leading thin metal plate, the purpose of which it is to simulate the thermal response of a silicon wafer. It is preferred according to the invention for firing to be carried out in a fast firing process with a total firing time in the range from about 20 s to about 3 minutes, more preferably in the range from about 20 s to about 2 minutes and most preferably in the range from about 20 s to about 40 s. The time above 600° C. is most preferably in a range from about 3 to 7 s.

Firing of electroconductive pastes on the front and back faces can be carried out simultaneously or sequentially. Simultaneous firing is appropriate if the electroconductive pastes applied to both faces have similar, preferably identical, optimum firing conditions. Where appropriate, it is preferred according to the invention for firing to be carried out simultaneously. Where firing is carried out sequentially, it is preferable according to the invention for the back electroconductive paste to be applied and fired first, followed by application and firing of the electroconductive paste to the front face.

### Solar Cell

A contribution to achieving at least one of the above described objects is made by a solar cell obtainable by a process according to the invention. Preferred solar cells according to the invention are those which have a high efficiency in terms of proportion of total energy of incident light converted into electrical energy output and which are light and durable. The minimum configuration of a solar cell according to the invention (excluding layers which are purely for chemical and mechanical protection) is as follows: (i) front electrode, (ii) front doped layer, (iii) p-n junction boundary, (iv) back doped layer, and (v) soldering pads.

### Passivation Layers

According to the invention, one or more passivation layers can be applied to the front and/or back side. Preferred passivation layers are those which reduce the rate of electron/hole recombination in the vicinity of the electrode interface. Any passivation layer which is known to the person skilled in the art and which he considers to be suitable in the context of the invention can be employed. Preferred passivation layers according to the invention are silicon nitride, silicon dioxide and titanium dioxide, silicon nitride being most preferred. According to the invention, it is preferred for the passivation layer to have a thickness in a range from about 0.1 nm to about 2 μm, more preferably in a range from about 10 nm to about 1 μm and most preferably in a range from about 30 nm to about 200 nm.

### Additional Protective Layers

In addition to the layers described above which directly contribute to the principle function of the solar cell, further layers can be added for mechanical and chemical protection.

The cell can be encapsulated to provide chemical protection. Encapsulations are well known to the person skilled in the art and any encapsulation can be employed which is known to him and which he considers suitable in the context of the invention. According to the invention, transparent polymers, often referred to as transparent thermoplastic resins, are preferred as the encapsulation material, if such an encapsulation is present. Preferred transparent polymers in this context are for example silicon rubber and polyethylene vinyl acetate (PVA).

A transparent glass sheet can be added to the front of the solar cell to provide mechanical protection to the front face of the cell. Transparent glass sheets are well known to the person skilled in the art and any transparent glass sheet known to him and which he considers to be suitable in the context of the invention can be employed as protection on the front face of the solar cell.

A back protecting material can be added to the back face of the solar cell to provide mechanical protection. Back protecting materials are well known to the person skilled in the art and any back protecting material which is known to the person skilled in the art and which he considers to be suitable in the context of the invention can be employed as protection on the back face of the solar cell. Preferred back protecting materials according to the invention are those having good mechanical properties and weather resistance. The preferred back protection material according to the invention is polyethylene terephthalate with a layer of polyvinyl fluoride. It is preferred according to the invention for the back protecting material to be present underneath the encapsulation layer (in the event that both a back protection layer and encapsulation are present).

A frame material can be added to the outside of the solar cell to give mechanical support. Frame materials are well known to the person skilled in the art and any frame material known to the person skilled in the art and which he considers suitable in the context of the invention can be employed as frame material. The preferred frame material according to the invention is aluminium.

### Solar Panels

A contribution to achieving at least one of the above mentioned objects is made by a module comprising at least a solar cell obtained as described above, in particular according to at least one of the above described embodiments, and at least one more solar cell. A multiplicity of solar cells according to the invention can be arranged spatially and electrically connected to form a collective arrangement called a module. Preferred modules according to the invention can take a number of forms, preferably a rectangular surface known as a solar panel. A large variety of methods to electrically connect solar cells, as well as a large variety of methods to mechanically arrange and fix such cells to form collective arrangements, are well known to the person skilled in the art, and any such methods known to him and which he considers suitable in the context of the invention can be employed. Preferred methods according to the invention are those which result in a low mass to power output ratio, low volume to power output ration, and high durability. Aluminium is the preferred material for mechanical fixing of solar cells according to the invention.

### Example 1

A first set of exemplary pastes (referred to as A-F) was prepared. The compositions of the exemplary pastes are set forth in Table 1. The exemplary pastes include a number of metals to test their effect on adhesion. The metals were added to the paste at about 0.5-1 wt. % of paste. The components of each paste were mixed together in a mixer and passed through a three roll mill to make a dispersed uniform paste.

The pastes were then screen printed onto the rear side of a blank silicon wafer using 250 mesh stainless steel, 5 μm EOM, at about a 30 μm wire diameter. The backside paste is printed to form soldering pads, which extend across the full length of the cell and are about 4 mm wide. However, different designs and screen parameters known to one skilled in the art can be used. Next, a different aluminum backside paste is printed all over the remaining areas of the rear side of the cell to form an aluminum BSF. The cell is then dried at an appropriate temperature. If electrical performance is to be tested, a standard front side paste is printed on the front side of the cell. The silicon substrate, with the printed front side and backside paste, is then fired at a temperature of approximately 700-975° C.

TABLE 1
Composition of First Set of Exemplary Pastes

| | A | B | C | D | E | F |
|---|---|---|---|---|---|---|
| Silver (wt. %) | 54 | 54 | 54 | 54 | 54 | 54 |
| Lead-free glass (wt. %) | 2 | 2 | 2 | 2 | 2 | 2 |
| Vehicle (wt. %) | 43 | 43 | 43 | 43 | 43 | 43 |
| Inorganic additive (wt. %) | ~1 | ~1 | ~1 | ~1 | ~1 | ~1 |
| Tungsten | + | | | | | |
| Molybdenum | | + | | | | |
| Vanadium | | | + | | | |
| Nickel | | | | + | | |
| Zinc | | | | | + | |
| Tellurium | | | | | | + |

The adhesive strength of the exemplary pastes was then measured according to procedure previously described. Pastes having no adhesion are indicated with “−”, and had pull forces of zero or close to zero. Pastes which exhibited pull forces between 2-5 Newton are indicated with “+”; pastes which exhibits pull forces between 5-8 Newton are indicated with “++”, and pastes which exhibited pull forces greater than 8 Newton are indicated with “+++.” As shown in Table 2, Exemplary Paste F provides excellent adhesion. Exemplary pastes A (W), D (Ni), and E (Zn) also exhibited acceptable adhesive strength.

TABLE 2
Adhesive Strength of First Set of Exemplary Pastes

| | A | B | C | D | E | F |
|---|---|---|---|---|---|---|
| Adhesive Strength | ++ | + | − | ++ | ++ | +++ |
| (Newtons) | | | | | | |
| | W | Mb | V | Ni | Zn | Te |

### Example 2

A second set of exemplary pastes (referred to as G-P) was prepared. The compositions of the exemplary pastes are set forth in Table 3. The exemplary pastes include varying oxides to test their effect on adhesion. The oxides were about 0.5-1 wt. % of the paste. Once the components were mixed to a uniform consistency, they were screen printed onto a silicon wafer according to the parameters set forth in Example 1.

TABLE 3
Composition of Second Set of Exemplary Pastes

| | G | H | I | J | K | L | M | N | O | P |
|---|---|---|---|---|---|---|---|---|---|---|
| Silver (wt. %) | 54 | 54 | 54 | 54 | 54 | 54 | 54 | 54 | 54 | 54 |
| Pb-free glass (wt. %) | 2 | 2 | 2 | 2 | 2 | 2 | 2 | 2 | 2 | 2 |
| Vehicle (wt. %) | 42.77 | 42.77 | 42.77 | 42.77 | 42.77 | 42.77 | 42.77 | 42.77 | 42.77 | 42.77 |
| Inorganic additive (wt. %) | ~1 | ~1 | ~1 | ~1 | ~1 | ~1 | ~1 | ~1 | ~1 | ~1 |
| Sb₂O₃ | + | | | | | | | | | |
| α-SiO₂ | | + | | | | | | | | |
| TeO₂ | | | + | | | | | | | |
| NiO | | | | + | | | | | | |
| MgO | | | | | + | | | | | |
| ZRO₂ | | | | | | + | | | | |
| WO₃ | | | | | | | + | | | |
| AgO | | | | | | | | + | | |
| CoO | | | | | | | | | + | |
| CeO₂ | | | | | | | | | | + |

The adhesive strength of the exemplary pastes was then measured as previously described. As shown in Table 4, the adhesive strength of Exemplary Paste I, containing tellurium oxide, provides excellent adhesion. Exemplary pastes J (NiO), K (MgO), L (ZrO₂), M (WO₃), and P (CeO₂) also exhibited acceptable adhesive strength.

TABLE 4
Adhesive Strength of Second Set of Exemplary Pastes

| | G | H | I | J | K | L | M | N | O | P |
|---|---|---|---|---|---|---|---|---|---|---|
| Adhesive Strength | − | − | +++ | ++ | ++ | ++ | ++ | + | + | ++ |
| (Newtons) | | | | | | | | | | |

### Example 3

A third set of exemplary pastes (referred to as Q-T) was prepared with exemplary lead-based glass frit and lead-free glass frit. Two reference pastes (referred to as Control 1 and Control 2) were also prepared. Control 1 and exemplary pastes Q and S contain a lead-based glass frit, and Control 2 and exemplary pastes R and T contain a lead-free glass frit. The compositions of the exemplary and references pastes are set forth in Table 5. The tellurium or tellurium oxide adhesion enhancer was about 0.5-1 wt. % of the paste. Once the pastes were mixed to a uniform consistency, they were screen-printed onto a silicon wafer according to the parameters set forth in Example 1.

TABLE 5
Composition of Reference Pastes and Third Set of Exemplary Pastes

| | Control 1 | Control 2 | Q | R | S | T |
|---|---|---|---|---|---|---|
| Silver (wt. %) | 54 | 54 | 54 | 54 | 54 | 54 |
| Pb-based glass (wt. %) | 2 | | 2 | | 2 | |
| Pb-free glass (wt. %) | | 2 | | 2 | | 2 |
| Vehicle (wt. %) | 43 | 43 | 43 | 43 | 43 | 43 |
| Inorganic additive (wt. %) | ~1 | ~1 | ~1 | ~1 | ~1 | ~1 |
| Tellurium | | | + | + | | |
| TeO₂ | | | | | + | + |

The adhesive strength of the reference pastes and exemplary pastes was then measured. As shown in Table 6, the adhesive strength of the lead-free exemplary pastes with adhesion enhancer performed better than the lead-free reference paste (Control 2). The lead-based exemplary pastes with adhesion enhancer also provide acceptable adhesion. It is environmentally more desirable to have lead-free paste compositions. It is thus advantageous that the adhesion enhancers of the present invention, e.g., tellurium oxide, provide better adhesion characteristics than the reference paste with lead-free glass frits.

TABLE 6
Adhesive Strength of Reference Pastes
and Third Set of Exemplary Pastes

| | Pb-based | | | Pb-free | | |
|---|---|---|---|---|---|---|
| | Control 1 | Q | s | Control 2 | R | T |
| Adhesive Strength | +++ | ++ | ++ | ++ | +++ | +++ |
| (Newtons) | | | | | | |

### Example 4

A fourth set of exemplary pastes was prepared (referred to as U, V, W and X), all having a tellurium oxide adhesion enhancer at about 0.2-0.7 wt. % of paste. The exemplary pastes incorporate different types of lead-free glass frits. A reference paste containing a leaded glass frit (referred to as Control) was also used for comparison. The compositions of the reference paste and exemplary pastes are set forth in Table 7. Once the pastes were mixed to a uniform consistency, they were screen printed onto a silicon wafer according to the parameters set forth in Example 1.

TABLE 7
Composition of Reference Paste and Fourth Set of Exemplary Pastes

| | Control 1 | U | V | W | X |
|---|---|---|---|---|---|
| Silver (wt. %) | 50 | 50 | 50 | 50 | 50 |
| Vehicle (wt. %) | 46 | 46 | 46 | 46 | 46 |
| Inorganic additive | ~1 | ~1 | ~1 | ~1 | ~1 |
| (wt. %) | | | | | |
| TeO₂ | | + | + | + | + |
| Pb-based glass | 3 | | | | |
| (wt. %) | | | | | |
| Bi—B—Li-oxide glass (wt. %) | | 3 | | | |
| Bi—Zn—B-oxide glass (wt. %) | | | 3 | | |
| Bi—Si—Zn—B-oxide glass (wt. %) | | | | 3 | |
| Bi—Si-oxide glass | | | | | 3 |
| (wt. %) | | | | | |

The adhesive strength of the reference paste and exemplary pastes were then measured as previously described. As shown in Table 8, the adhesive strength of the lead-free exemplary pastes containing tellurium dioxide performed consistently better with all tested lead-free glass frits than the lead-based control paste.

TABLE 8
Adhesive Strength of Reference Paste and Fourth Set of Exemplary
Pastes

| | Control | U | V | W | X |
|---|---|---|---|---|---|
| Adhesive Strength | + | ++ | ++ | ++ | ++ |
| (Newtons) | | | | | |

### Example 5

A fifth set of exemplary pastes (referred to as Z and AA) was prepared using tellurium oxide and tellurium metal adhesion enhancers with the same lead free Bi—Si-oxide glass frit. The tellurium oxide and tellurium metal adhesion enhancers were about 0.01-0.5 wt. % of paste. The same molar amount of tellurium (Te) was present in both exemplary pastes. The compositions of the exemplary pastes are set forth in Table 9. Once the pastes were mixed to a uniform consistency, they were screen printed onto a silicon wafer according to the parameters set forth in Example 1.

TABLE 9
Composition of Fifth Set of Exemplary Pastes

| | Z | AA |
|---|---|---|
| Silver (wt. %) | 50 | 50 |
| Vehicle (wt. %) | 47 | 47 |
| Inorganic additive (wt. %) | <1 | <1 |
| Bi—Si-oxide glass (wt. %) | 3 | 3 |
| TeO₂ | + | |
| Te | | + |

The adhesive strength of the exemplary pastes was measured as previously described. As shown in Table 10, the adhesive strength of the exemplary pastes containing elemental tellurium metal performed equally as well as the exemplary paste containing tellurium oxide.

TABLE 10
Adhesive Strength of Fifth Set of Exemplary Pastes

| | Z | AA |
|---|---|---|
| Adhesive Strength | ++ | ++ |
| (Newtons) | | |

### Example 6

A sixth exemplary paste (referred to as BB) was prepared with about 50 wt. % silver particles, about 3 wt. % Bi—Si-oxide glass frit, about 47 wt. % organic vehicle, less than 1 wt. % inorganic additive, and about 0.01-0.5 wt. % tellurium oxide adhesion enhancer. Once the paste was mixed to uniform consistency, it was screen printed onto the backside of a silicon wafer according to the parameters set forth in Example 1. A front side paste was applied to the silicon wafer to prepare the cell for electrical performance testing. Lastly, the adhesive strength of the exemplary paste was measured on both a monocrystalline silicon wafer (cz-Si) and a multi-crystalline silicon wafer (mc-Si). A standard backside reference paste known in the art (referred to as Ref.) was used for comparison of adhesive strength and electrical performance.

The adhesive properties of the exemplary paste are set forth in Table 9, and the electrical performance of the resulting solar cell is set forth in Table 10. The electrical performance of the reference and exemplary solar cells was tested using an I-V tester. A xenon are lamp in the I-V tester was used to simulate sunlight with a known intensity and the front surface of the solar cell was irradiated to generate the I-V curve. Using this curve, various parameters common to this measurement method which provide for electrical performance comparison were determined, including solar cell efficiency (NCell), short circuit current density (Isc), open circuit voltage (Voc), fill factor (FF), series resistance (Rs), maximum power point (Pmpp), reverse current at −10V (Irev1) and reverse current at −12V (Irev2). All measurements are normalized to the reference paste. Number of tests performed (N) for each sample are indicated in Table 10.

TABLE 9
Adhesive Strength of Reference Paste and Sixth Exemplary Paste

| | |
|---|---|
| cz-Si | mc-Si |

| | Ref. | BB | Ref. | BB |
|---|---|---|---|---|
| Adhesive Strength | ++ | ++ | + | ++ |
| (Newtons) | | | | |

TABLE 10
Electrical Performance of Reference Paste and Sixth Exemplary Paste

| | | | Avg. Print | | | | | | | | |
|---|---|---|---|---|---|---|---|---|---|---|---|
| | Paste | N | Wt. (mg) | NCell | Isc | Voc | FF | Rs | Pmpp | Irev1 | Irev2 |
| cz-Si | Ref. | 8 | 103 | 1.00 | 1.00 | 1.00 | 1.00 | 1.00 | 1.00 | 1.00 | 1.00 |
| | BB | 8 | 103 | 1.0176 | 1.0120 | 1.0114 | 0.9962 | 1.0880 | 1.0172 | 1.1068 | 1.0968 |
| mc-Si | Ref. | 7 | 100 | 1.00 | 1.00 | 1.00 | 1.00 | 1.00 | 1.00 | 1.00 | 1.00 |
| | BB | 8 | 104 | 1.00 | 0.9975 | 1.0033 | 1.00 | 0.9898 | 1.00 | 0.8333 | 0.8636 |

As can be seen from Table 9, the exemplary paste exhibited an adhesive strength comparable to that of the reference paste when tested on a monocrystalline silicon wafer, and exhibited an improved adhesive strength as compared to the reference paste when tested on a multi-crystalline silicon wafer. Further, the exemplary paste exhibited an electrical performance comparable to or better than that of the reference paste, both on a monocrystalline and multi-crystalline silicon wafer.

### Example 7

A seventh set of exemplary pastes was prepared, whereby the tellurium dioxide adhesion enhancer was either incorporated into the glass frit (CC), or added directly to the composite paste mixture independent of the glass frit (Z). Both exemplary pastes were also prepared with the Bi—Si-oxide glass frit. The same amount of the tellurium oxide adhesion enhancer was present in both exemplary pastes at about 0.01-0.5 wt. % (based upon 100% total weight of the paste). Exemplary paste CC was prepared with the same formulation as the exemplary paste Z, except that the tellurium oxide in the exemplary pastes CC was incorporated into the glass frit, prior to mixing into the paste composition as a whole. The compositions of the exemplary pastes are set forth in Table 11. Once the pastes were mixed to uniform consistency, they were screen printed onto the backside of a silicon wafer according to the parameters set forth in Example 1.

TABLE 11
Composition of Seventh Set of Exemplary Pastes

| | Z | CC |
|---|---|---|
| Silver (wt. %) | 50 | 50 |
| Bi—Si-oxide glass (wt. %) | 3 | 3 |
| Vehicle (wt. %) | 47 | 47 |
| Inorganic additive | <1 | <1 |
| (wt. %) | | |
| TeO₂ in paste | + | |
| TeO₂ in glass phase | | + |

The adhesive strength of the exemplary pastes was then measured. As shown in Table 12, the adhesive strength of the exemplary paste having tellurium dioxide incorporated in the glass frit (CC) performed equally to the exemplary paste with tellurium dioxide added directly to the paste composition.

TABLE 12
Adhesive Strength of Seventh set of Exemplary Pastes

| | Z | CC |
|---|---|---|
| Adhesive Strength | ++ | ++ |
| (Newtons) | | |

These and other advantages of the present invention will be apparent to those skilled in the art from the foregoing specification. Accordingly, it will be recognized by those skilled in the art that changes or modifications may be made to the above described embodiments without departing from the broad inventive concepts of the invention. Specific dimensions of any particular embodiment are described for illustration purposes only. It should therefore be understood that this invention is not limited to the particular embodiments described herein, but is intended to include all changes and modifications that are within the scope and spirit of the invention.

1. An electroconductive paste composition for use in forming backside soldering pads on a solar cell comprising:
metallic particles;
glass frits;
organic vehicle; and
an adhesion enhancer comprising a metal or a metal oxide, or any other metal compound that will convert to a metal or metal oxide at firing temperature, wherein the adhesion enhancer comprises at least one metal selected from the group consisting of tellurium, tungsten, molybdenum, vanadium, nickel, antimony, magnesium, zirconium, silver, cobalt, cerium, and zinc, or oxides thereof.

2. The electroconductive paste composition according to claim 1, wherein the adhesion enhancer is at least one metal selected from the group consisting of tellurium, tungsten, molybdenum, nickel, and zinc.

3. The electroconductive paste composition according to claim 1, wherein the adhesion enhancer is tellurium.

4. The electroconductive paste composition according to claim 1, wherein the adhesion enhancer is at least one metal oxide selected from the group consisting of tellurium dioxide, nickel oxide, magnesium oxide, zirconium dioxide, tungsten oxide, silver oxide, cobalt oxide and cerium oxide.

5. The electroconductive paste composition according to claim 4, wherein the adhesion enhancer is tellurium dioxide.

6. The electroconductive paste composition according to claim 1, wherein the adhesion enhancer is about 0.01-5 wt. % of the electroconductive paste composition.

7. (canceled)

8. The electroconductive paste composition according to claim 1, wherein the adhesion enhancer is dispersed within the glass frits.

9. The electroconductive paste composition according to claim 1, wherein the adhesion enhancer is dispersed within the paste composition independent from the glass frits.

10. The electroconductive paste composition according to claim 1, wherein the metallic particles are about 30-75 wt. % of the electroconductive paste composition.

11. (canceled)

12. (canceled)

13. The electroconductive paste composition according to claim 1, wherein the metallic particles are at least one of silver, aluminum, gold and nickel, or any alloys thereof.

14. The electroconductive paste composition according to claim 13, wherein the metallic particles are silver.

15. The electroconductive paste composition according to claim 1, wherein the glass frits are about 1-10 wt. % of the electroconductive paste composition.

16. The electroconductive paste composition according to claim 1, wherein the glass frits comprise lead oxide.

17. The electroconductive paste composition according to claim 1, wherein the glass frits comprise no intentionally added lead.

18. (canceled)

19. The electroconductive paste composition according to claim 1, wherein the glass frits comprise at least one of Bi—B—Li-oxide, Bi—Zn—B-oxide, Bi—Si—Zn—B-oxide or Bi—Si-oxide.

20. (canceled)

21. (canceled)

22. (canceled)

23. (canceled)

24. (canceled)

25. A solar cell comprising:
a silicon wafer having a front side and a backside; and
a soldering pad formed on the silicon wafer produced from an electroconductive paste according to claim 1.

26. A solar cell according to claim 25, wherein the soldering pad is formed on the backside of the solar cell.

27. A solar cell according to claim 25, wherein the soldering pad may be removed from the silicon wafer with a pull force equal to or greater than 1-Newton.

28. (canceled)

29. (canceled)

30. (canceled)

31. A solar cell according to any one of claim 25, wherein the soldering pad is formed from an electroconductive paste comprising about 30-75 wt. % of metallic particles.

32. (canceled)

33. (canceled)

34. (canceled)

35. (canceled)

36. (canceled)

37. (canceled)

38. (canceled)

39. (canceled)

40. A method of producing of a solar cell, comprising the steps of:
providing a silicon wafer having a front side and a backside;
applying an electroconductive paste composition according to claim 1 onto the backside of the silicon wafer; and
firing the silicon wafer according to an appropriate profile to yield a soldering pad.

41. (canceled)

42. (canceled)

43. (canceled)

44. (canceled)
